(19) United States
(12) Patent Application Publication
(10) Pub. No.: US 2025/0220785 A1
(43) Pub. Date: Jul. 3, 2025

(54) MODULAR FRAMING SUSPENSION SYSTEM WITH SPRINGS AND PLASTIC SNAPS

(71) Applicant: WHIRLPOOL CORPORATION, BENTON HARBOR, MI (US)

(72) Inventors: Cristian David Beltran Aponte, Joinville (BR); Fabiano Chinazzo, Cassinetta (IT); Rodrigo Tamanini, Joinville (BR)

(73) Assignee: WHIRLPOOL CORPORATION, BENTON HARBOR, MI (US)

(21) Appl. No.: 18/397,290

(22) Filed: Dec. 27, 2023

(51) Int. Cl. H05B 6/12; H05K 1/02; H05K 7/20

(52) U.S. Cl. CPC H05B 6/1245; H05K 1/0201; H05K 7/20136; H05K 2201/066

(57) ABSTRACT

A cooktop including: (a) a substrate including (i) a top surface configured to accept a vessel placed thereupon for heating and (ii) a bottom surface, the top surface and the bottom surface facing in generally opposing directions; (b) a structural support disposed below the substrate; (c) a platform disposed above the structural support, the platform comprising apertures; and (d) an induction coil disposed upon the platform and fastened to the platform with fasteners that extend through at least a portion of the apertures of the platform, the induction coil including a top surface that faces the bottom surface of the substrate, wherein, the apertures of the platform are positioned to permit fastening of the induction coil in one of several positions or several of the induction coils of more than one size in more than one spatial arrangement.

### BACKGROUND OF THE DISCLOSURE

The present disclosure pertains to a cooktop and, more particularly, a cooktop with a substrate presenting a cooking surface and a suspension system holding the induction element below the substrate and allowing arrangement of the induction element to be modified by a user.

A cooktop is a kitchen appliance that can deliver heat to a vessel to increase the temperature of a food item placed therein. Cooktops typically deliver heat via the combustion of a flammable gas, electrical resistance, or induction. An induction cooktop includes an induction coil and a substrate (e.g., a glass-ceramic substrate) disposed above the induction coil. The substrate provides a top surface upon which the vessel with the food item is placed. The vessel is ferromagnetic. The induction coil generates a rapidly changing magnetic field. The rapidly changing magnetic field generates eddy currents in the ferromagnetic vessel, which is resisted and thus creates heat. The heat increases the temperature of the food item within the vessel. Sometimes the induction cooktop includes multiple induction coils, and the induction coils may not all be identically sized.

The strength of the magnetic field that the induction coil generates follows an inverse-square relationship with distance from the induction coil. Thus, the further away the vessel is from the induction coil, the weaker the magnetic field interacting with the vessel. To decrease the distance between the induction coil and the vessel, the induction coil can be made to contact a bottom surface of the substrate.

However, there is a problem in that a user of the cooktop does not have the ability to change a spatial arrangement of the induction coils, or substitute induction coils of one size for induction coils of another size.

Further, there is a problem in that contact between the induction coil and the bottom surface of the substrate can cause the substrate to bend. The bend generates a tensile stress within the substrate contiguous with the top surface. The tensile stress makes the substrate more vulnerable to fracture during an impact event at the top surface, such as the dropping of the vessel upon the top surface.

### SUMMARY OF THE DISCLOSURE

The present disclosure addresses those problems with a platform for the induction coils with numerous apertures to provide numerous fastener placement options to fasten the induction coils to the platform. The numerous apertures allow the position of any particular induction coil to be changed and allow for changing the spatial arrangement and sizes of the induction coils. In addition, a structural support cooperates with coiled springs to cause the induction coils to contact the substrate but not impart sufficient upward force upon the substrate to cause the substrate to flex and generate the tensile stress at the top surface thereof.

According to one aspect of the present disclosure, a cooktop comprises: (a) a substrate comprising (i) a top surface configured to accept a vessel placed thereupon for heating and (ii) a bottom surface, the top surface and the bottom surface facing in generally opposing directions; (b) a structural support disposed below the substrate; (c) a platform disposed above the structural support, the platform comprising apertures; and (d) an induction coil disposed upon the platform and fastened to the platform with fasteners that extend through at least a portion of the apertures of the platform, the induction coil comprising a top surface that faces the bottom surface of the substrate, wherein, the apertures of the platform are positioned to permit fastening of the induction coil in one of several positions or several of the induction coils of more than one size in more than one spatial arrangement.

According to another aspect of the present disclosure, a cooktop comprises: (a) a substrate presenting (i) a top surface configured to accept a vessel placed thereupon for heating and (ii) a bottom surface; (b) a structural support disposed below the substrate, the structural support comprising a floor and studs extending upward from the floor; (c) coiled springs, each defining an inner core and comprising a bottom end and a top end, each of the coiled springs disposed around a different one of the studs of the structural support with the stud extending vertically through the inner core of the coiled spring; (d) a platform disposed above the structural support, the platform comprising (i) apertures through which the studs of the structural support extend, (ii) a bottom surface set upon the top end of each of the coiled springs, (iii) at least two panels, each of the at least two panels comprising a length at least 4 times greater than a width thereof, the lengths of the at least two panels disposed parallel to each other, and the at least two panels are spaced apart from each other, (iv) at least three cross-panels, each of the at least three cross-panels comprising a length at least 4 times greater than a width thereof, the lengths of the at least three cross-panels disposed parallel to each other but orthogonal to the lengths of the at least two panels, and the at least three cross-panels are spaced apart from each other, and (v) the at least three cross-panels of the platform are layered upon the at least two panels of the platform, with bottom surfaces of the at least three cross-panels contacting top surfaces of the at least two panels; and (e) an induction coil disposed upon the platform, the induction coil comprising a top surface that faces the bottom surface of the substrate, wherein, the coiled springs are in a partially excited state pushing the platform in an upward direction so that the top surface of the induction coil contacts the bottom surface of the substrate.

These and other features, advantages, and objects of the present disclosure will be further understood and appreciated by those skilled in the art by reference to the following specification, claims, and appended drawings.

### BRIEF DESCRIPTION OF THE DRAWINGS

In the drawings:

FIG. 1 is a perspective view of a cooktop of the present disclosure set into a countertop, illustrating the cooktop including a substrate exposed to an external environment and a vessel on the substrate with a food item for performing a cooking operation using the cooktop;

FIG. 2 is an overhead perspective view of the cooktop of FIG. 1, illustrating the substrate disposed over a cabinet that houses other components to be herein described;

FIG. 3 is a front overhead perspective exploded view of the cooktop of FIG. 1, illustrating induction coils under the substrate, a platform for the induction coils under the substrate, and a structural support for the platform under the platform;

FIG. 4 is a front underneath perspective exploded view of the cooktop similar to FIG. 3;

FIG. 5 is a front elevational view of the cooktop of FIG. 1, illustrating the structural support within the cabinet below a bottom surface of the substrate;

FIG. 6 is a side elevational view of a cross-section of the cooktop of FIG. 1 taken through line VI-VI of FIG. 5, illustrating the structural support including a stud and supporting a heat sink with an additional stud that support the platform along with a coiled and an additional coiled spring to both push the induction coils against the bottom surface of the substrate and to dampen an impact event upon the top surface of the substrate;

FIG. 7 is an overhead perspective view of a cross-section of the cooktop of FIG. 1 taken through line VII-VII of FIG. 5, illustrating the structural support including trays that hold fans, the heat sinks, and electrical components;

FIG. 8 is an overhead perspective view of the structural support, illustrating the studs including a bottom portion with a larger diameter than a top portion;

FIG. 9 is plan view of the structural support;

FIG. 10 is a front elevational view of the structural support; illustrating the studs extending in an upward direction;

FIG. 11 is a magnified view of area X of FIG. 9, illustrating the studs including a ledge separating the bottom portion from the top portion;

FIG. 12 is an overhead perspective view of a cross-section of the cooktop of FIG. 1 taken through line XII-XII of FIG. 5, illustrating the platform including two panels oriented from one lateral direction to another lateral direction and four cross-panels oriented from a forward direction to a rearward direction layered over the two panels to form a grid to support the induction coils against the bottom surface of the substrate;

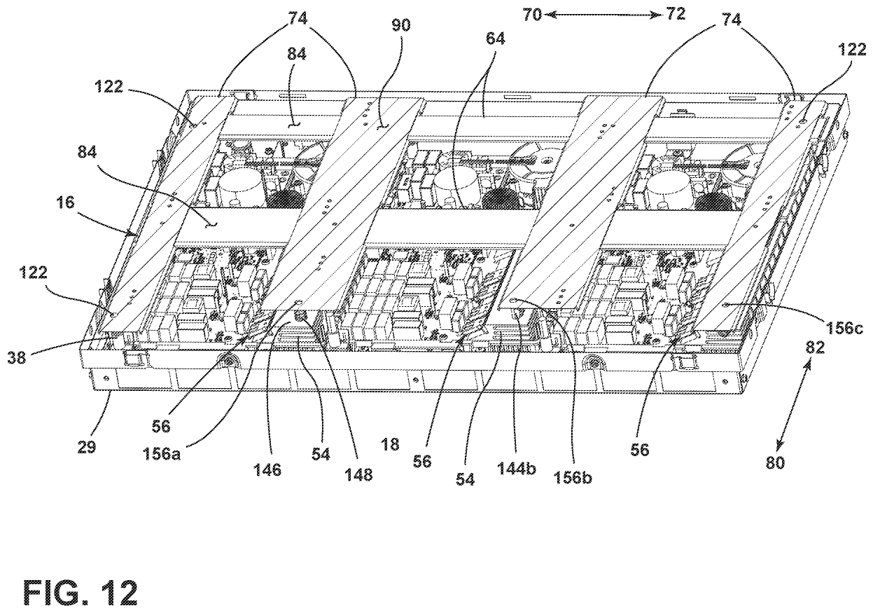

FIG. 13 is an overhead view of the platform, illustrating groupings of apertures therethrough to provide numerous connection opportunities for the induction coils;

FIG. 14 is an underneath view of the platform, illustrating that some of the apertures of the platform go through only the four cross-panels while some of the apertures of the platform go through both the four cross-panels and the two panels oriented orthogonally to the four cross-panels;

FIG. 15 is an elevation view of the platform, illustrating that the two panels and the four cross-panels each have a thickness that is much smaller than the widths and lengths of the same (along the horizontal plane);

FIG. 16 is an overhead perspective view of a cross-section of the cooktop taken along XVI-XVI of FIG. 5, illustrating the induction coils fastened to the platform with fasteners that extend through the apertures of the platform;

FIG. 17 is an underneath view of the induction coils fastened to the platform, illustrating that some of the apertures are left unused and that the induction coils could be repositioned upon the platform according to user desire;

FIG. 18 is the same view as FIG. 17 but this time illustrating (in phantom view) induction coils of different sizes and in different spatial relationships upon the platform compared to the induction coils of FIG. 17, which is made possible by the multiple groupings of apertures through the platform;

FIG. 19 is an overhead view of the cooktop of FIG. 1;

FIG. 20 is a rear elevational view of a cross-section of the cooktop of FIG. 1 taken through line XX-XX of FIG. 19, illustrating the coiled springs around the studs of the platform in a partially excited state pushing the platform in the upward direction and thus the top surface of the induction coils up against the bottom surface of the substrate;

FIG. 21 is a magnified view of area XXI of FIG. 20, illustrating the coiled spring set upon a ledge that the bottom portion of the stud of the structural support forms;

FIG. 22 is the same view as FIG. 21 but this time showing the coiled spring being forced into a more excited state in response to a force in the downward direction upon the top surface, thus dampening the force;

FIG. 23 is a front elevational view of a cross-section of the cooktop of FIG. 1 taken through line XXIII-XXIII of FIG. 20, illustrating the heat sinks each including an additional stud with an additional coiled spring disposed therearound and in communication with the platform; and

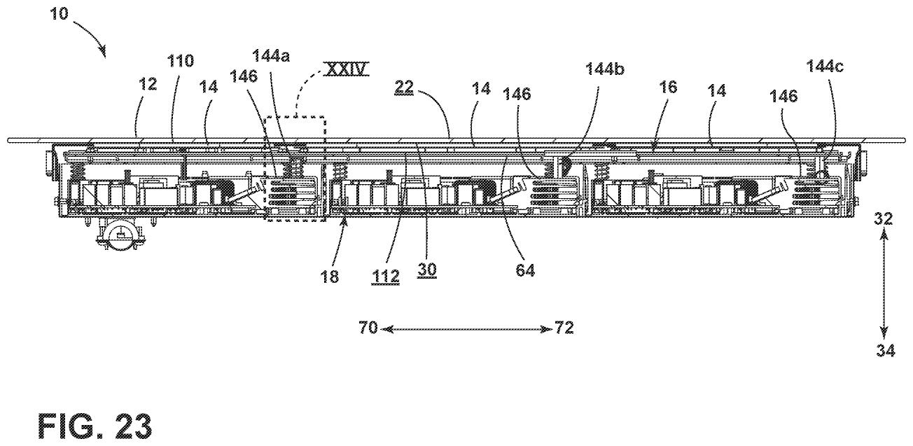

FIG. 24 is a magnified view of area XXIV of FIG. 23, illustrating the platform including an additional aperture through which the additional stud of the heat sink can extend.

The components in the figures are not necessarily to scale, emphasis instead being placed upon illustrating the principles described herein.

### DETAILED DESCRIPTION

The present illustrated embodiments reside primarily in combinations of method steps and apparatus components related to a cooktop and, more particularly, a cooktop with a substrate presenting a cooking surface and a suspension system holding an induction element below the substrate and allowing arrangement of the induction element to modified by a user. Accordingly, the apparatus components and method steps have been represented, where appropriate, by conventional symbols in the drawings, showing only those specific details that are pertinent to understanding the embodiments of the present disclosure so as not to obscure the disclosure with details that will be readily apparent to those of ordinary skill in the art having the benefit of the description herein. Further, like numerals in the description and drawings represent like elements.

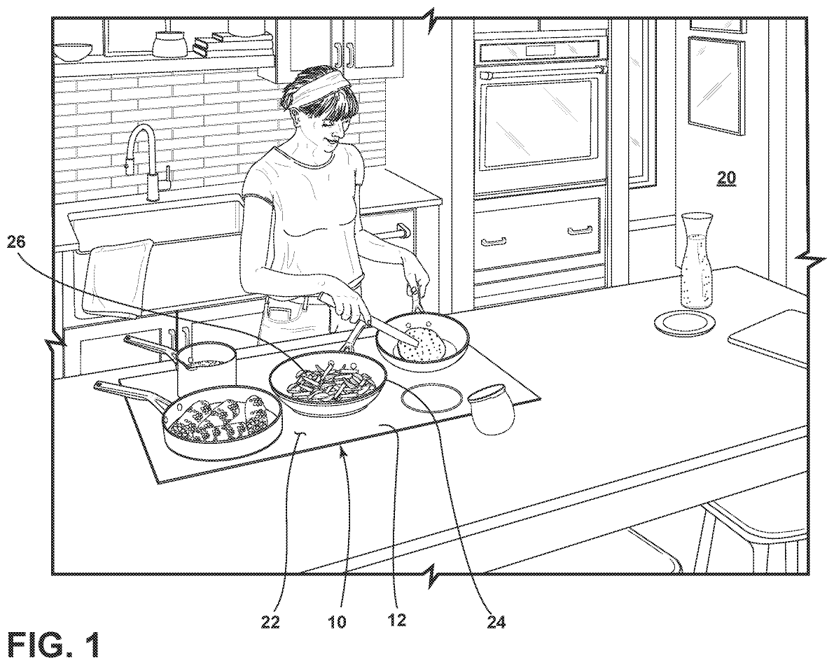

For purposes of description herein, the terms “upper,” “lower,” “right,” “left,” “rear,” “front,” “vertical,” “horizontal,” and derivatives thereof shall relate to the disclosure as oriented in FIG. 1. Unless stated otherwise, the term “front” shall refer to the surface of the element closer to an intended viewer, and the term “rear” shall refer to the surface of the element further from the intended viewer. However, it is to be understood that the disclosure may assume various alternative orientations, except where expressly specified to the contrary. It is also to be understood that the specific devices and processes illustrated in the attached drawings, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

The terms “including,” “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises a . . . ” does not, without more constraints, preclude the existence of additional identical elements in the process, method, article, or apparatus that comprises the element.

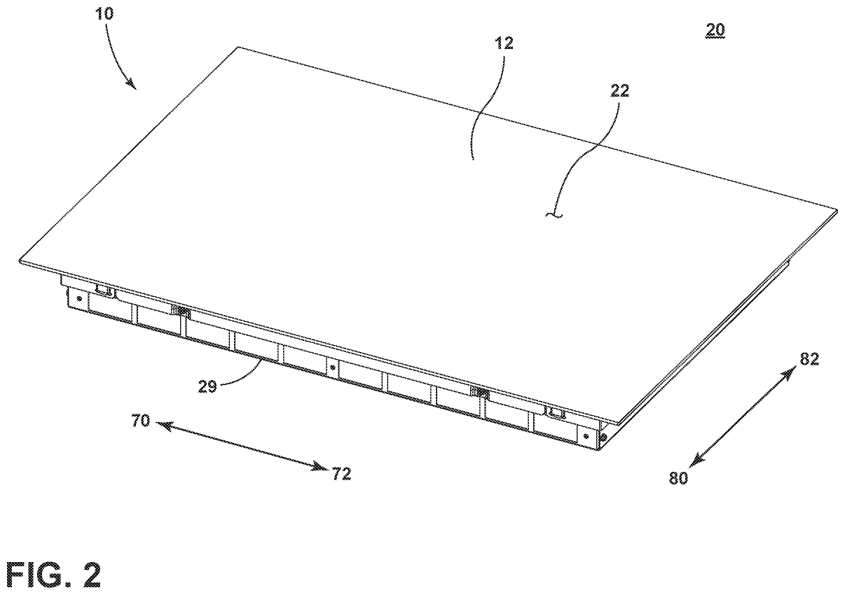

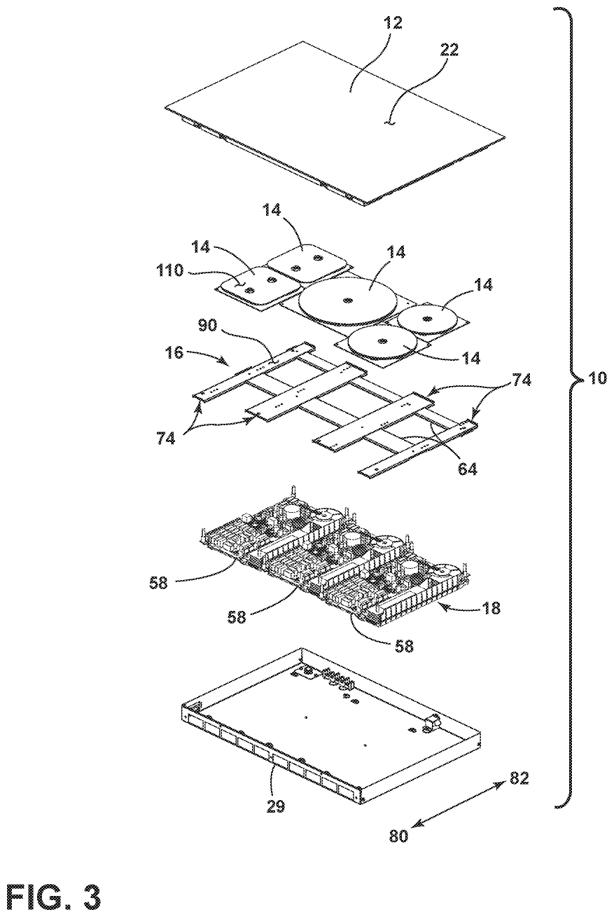

Referring now to FIGS. 1-3, a cooktop 10 includes a substrate 12, an induction coil 14 below the substrate 12, a platform 16 for the induction coil 14, and a structural support 18 supporting the platform 16. The substrate 12 separates from the induction coil 14, platform 16, and structural support 18 from an external environment 20. The substrate 12 includes a top surface 22 facing the external environment 20. The top surface 22 is configured to accept a vessel 24 placed thereupon for heating, such as during a cooking operation of a food item 26 placed within the vessel 24. For example, the top surface 22 can substantially form a horizonal plane. The top surface 22 can be substantially flush with a countertop 28 (as illustrated) or can be placed upon an oven range, among other options. A cabinet 29 below the substrate 12 houses the induction coil 14, the platform 16, and the structural support 18. The cabinet 29 can be made of a sheet metal such as aluminum.

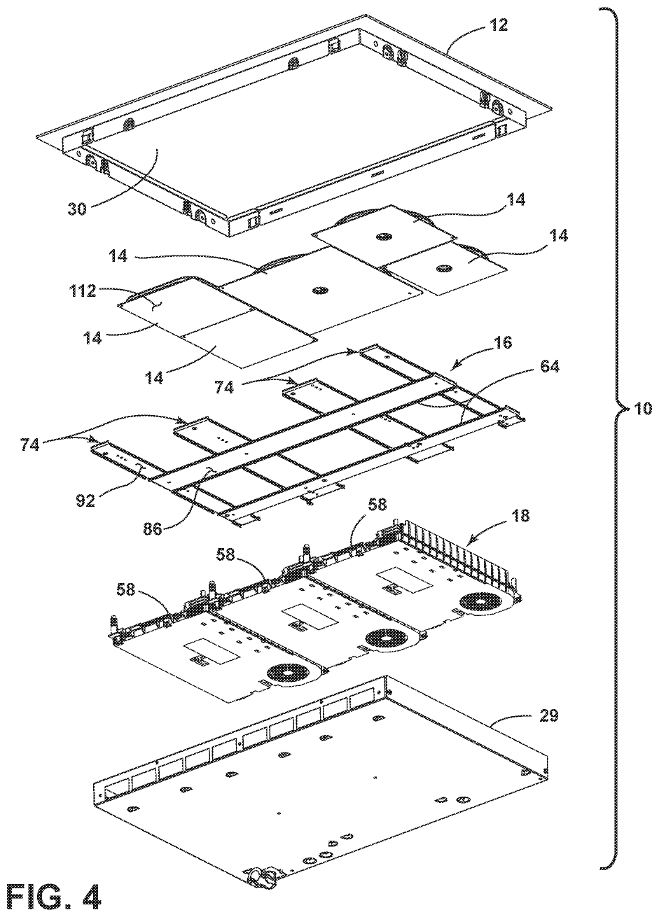

Referring additionally to FIG. 4, the substrate 12 further includes a bottom surface 30 in addition to the top surface 22. The top surface 22 and the bottom surface 30 face in generally opposing directions. For example, when the cooktop 10 is in use, the top surface 22 faces an upward direction 32 while the bottom surface 30 faces a downward direction 34. The substrate 12 can have a glass-ceramic composition, a ceramic composition, a nonferrous metallic composition, among other options. The substrate 12 can have a degree of transparency or can be opaque.

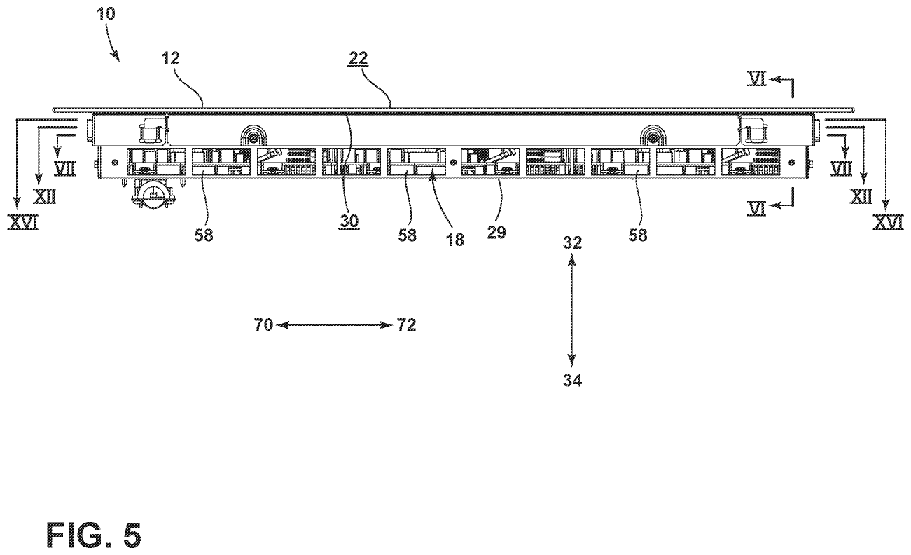

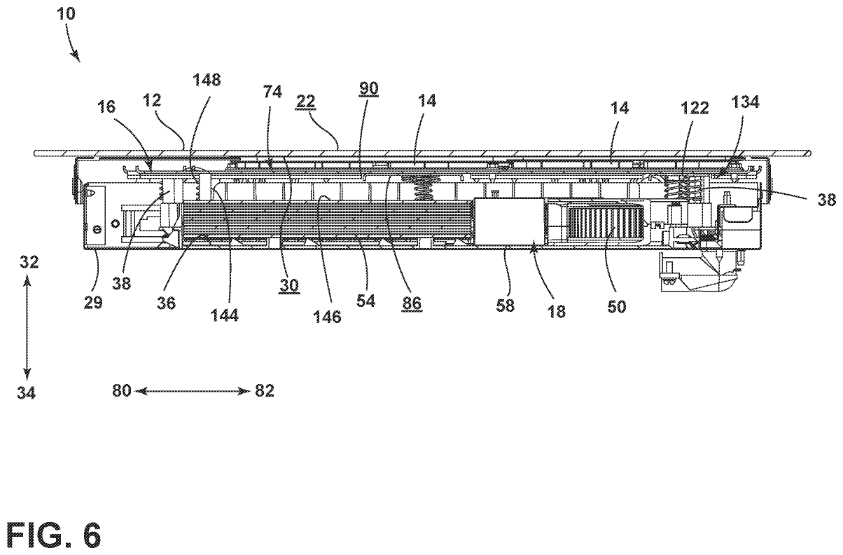

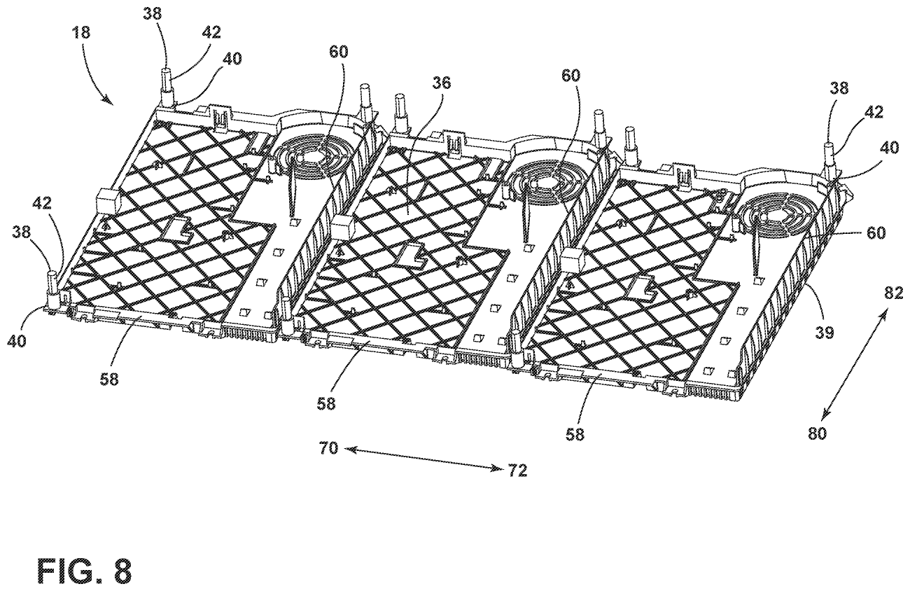

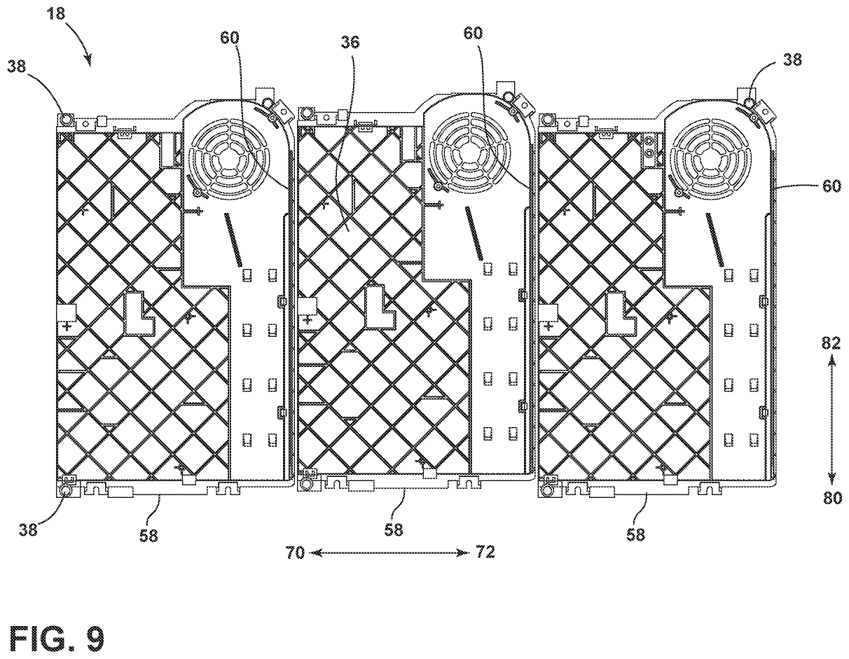

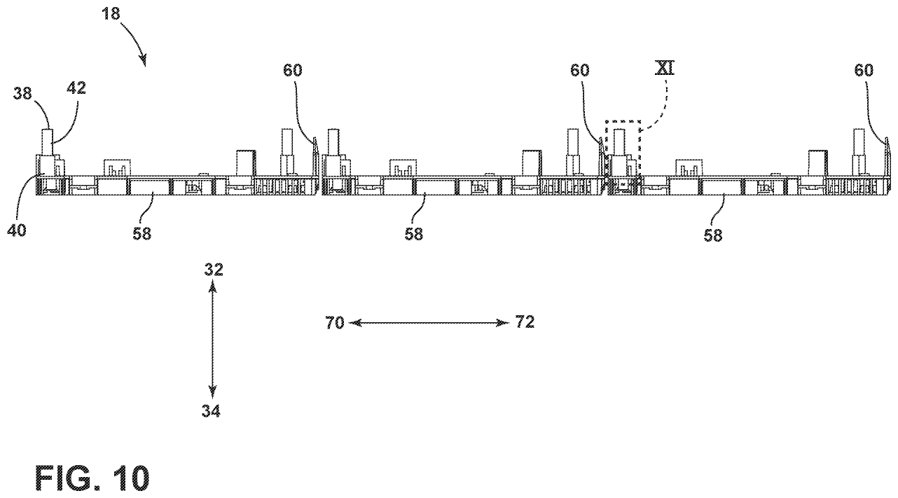

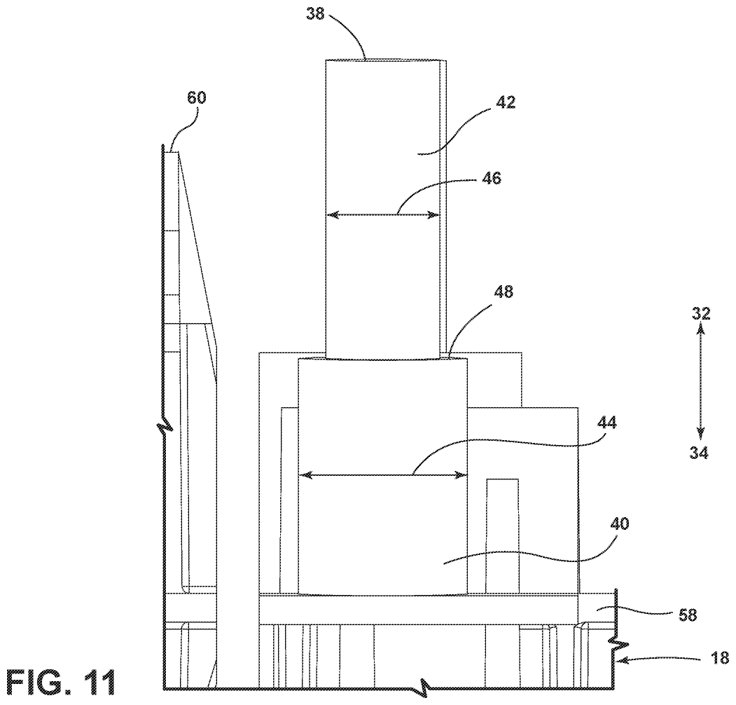

Referring additionally to FIGS. 5-11, the structural support 18 is disposed below the substrate 12. The structural support 18 structurally supports the platform 16 and, through the platform 16, the induction coil 14, as will be further discussed. The structural support 18 includes a floor 36 and studs 38 that extend upward relative to the floor 36. The studs 38 can have a circular horizontal cross-section. The studs 38 can be arranged adjacent (e.g., within 20 mm, within 10 mm, or within 5 mm) a horizontal perimeter 39 of the structural support 18. Each stud 38 can have a bottom portion 40 and a top portion 42 above the bottom portion 40. The horizontal cross-section of the stud 38 at the bottom portion 40 can have diameter 44 (see FIG. 11) that is larger than a diameter 46 of the horizontal cross-section of the stud 38 at the top portion 42. The bottom portion 40 can form a ledge 48 from which the top portion 42 extends.

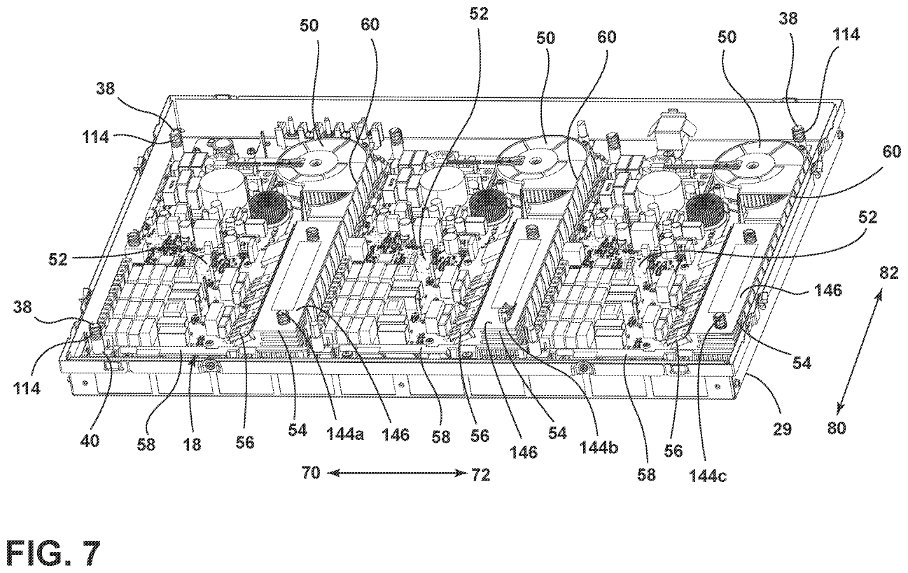

In embodiments, the cooktop 10 further includes a fan 50 (see, e.g., FIG. 7), a printed circuit board 52, and a heat sink 54. The fan 50 is positioned to force air over the heat sink 54. The heat sink 54 is positioned to withdraw heat from electrical components 56 of the printed circuit board 52. The electrical components 56 can control operation of the induction coil 14 connected to the printed circuit board 52. More than one induction coil 14 can be connected to any particular printed circuit board 52. The printed circuit board 52, the fan 50, and the heat sink 54 are above the floor 36 of the structural support 18 and elevationally below the induction coil 14. The structural support 18 supports, and can partially house, the fan 50, the printed circuit board 52, and the heat sink 54. The cooktop 10 can include multiple fans 50, multiple printed circuit boards 52, and multiple heat sinks 54.

In embodiments, the structural support 18 includes two or more trays 58. In the illustrated embodiment, the structural support 18 includes three trays 58 disposed next to each other and which may be connected to each other. Each of the two or more trays 58 are substantially identical to each other. For example, each of the two or more trays 58 can have a plastic composition and a shape molded from the same mold. Each of the two or more trays 58 house one of the fans 50, one of the printed circuit boards 52, and one of the heat sinks 54. Each tray 58, and thus the structural support 18 generally, can include a vertical wall 60 (see, e.g., FIG. 7) separating the heat sink 54 disposed in the tray 58 from the printed circuit board 52 of an adjacent tray 58. Instead or in addition to plastic, the structural support 18 can be made of (or have components made of) metal or other materials.

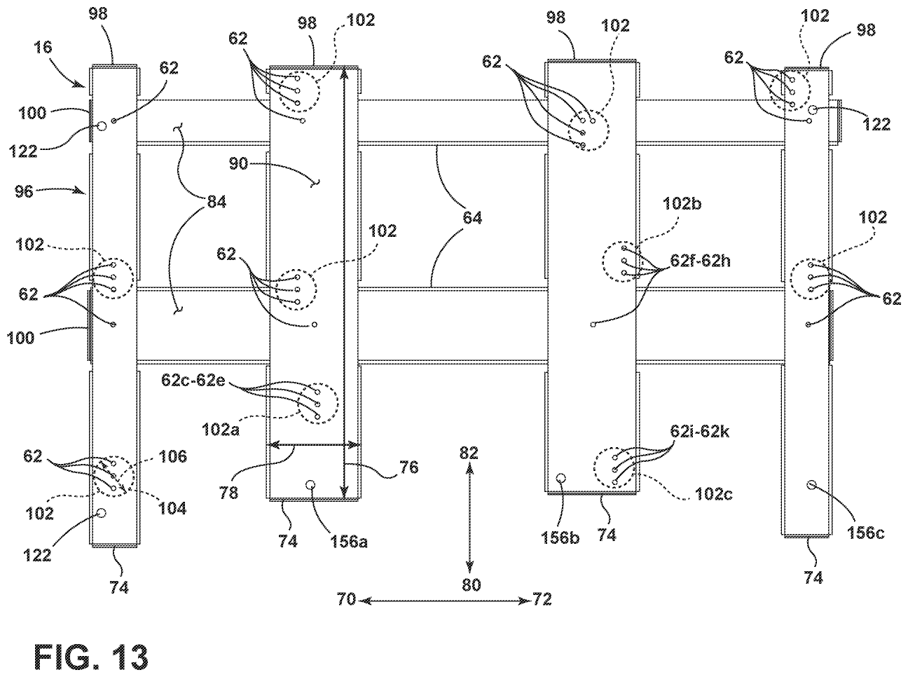

Referring additionally to FIGS. 13-15, as mentioned, the cooktop 10 further includes the platform 16. The platform 16 supports the induction coil 14. The platform 16 is disposed above the structural support 18, such as elevationally above the floor 36 of the structural support 18. The platform 16 includes apertures 62 (see, e.g., FIG. 13). As will be discussed, the apertures 62 provide a multitude of fastening opportunities for the induction coil 14 or induction coils 14 of the cooktop 10.

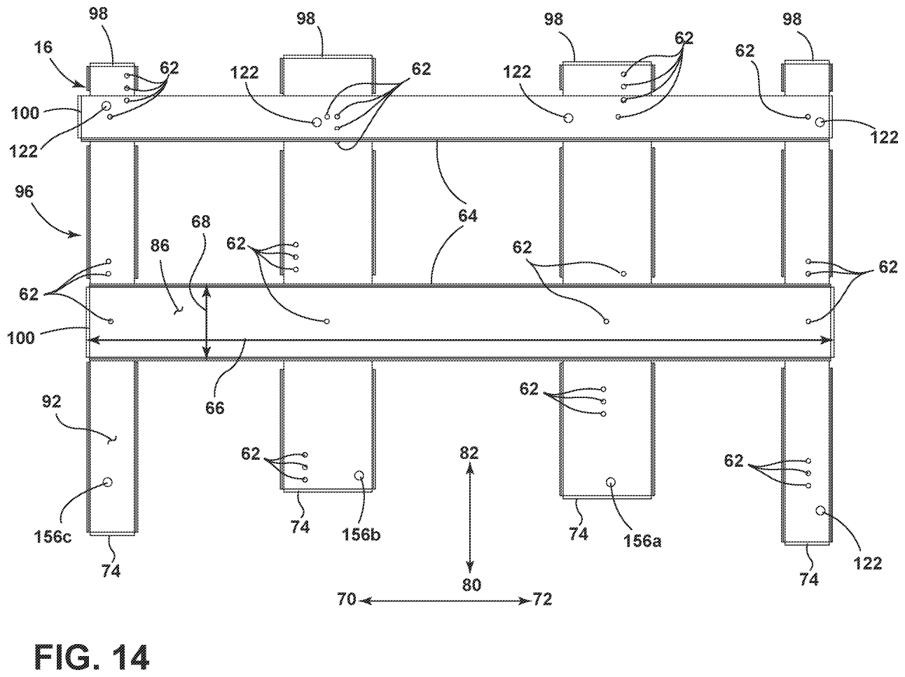

In embodiments, the platform 16 includes at least two panels 64 (two such panels 64 are illustrated). Each of the at least two panels 64 has a length 66 (see, e.g., FIG. 14) and a width 68 (both in same plane, e.g., the horizontal plane). The length 66 of each of the at least two panels 64 is at least 4 times greater than the width 68 thereof. The lengths 66 of the at least two panels 64 are disposed parallel to each other. For example, the lengths 66 of the at least two panels 64 can extend in lateral directions 70, 72. The at least two panels 64 are spaced apart from each other.

In addition, in embodiments, the platform 16 further includes at least three cross-panels 74 (four such cross-panels 74 are illustrated). Each of the at least three cross-panels 74 has a length 76 (see FIG. 13) and a width 78 (both in the same plane, e.g., the horizontal plane). The length 76 of each of the at least three cross-panels 74 is at least 4 times greater than the width 78 thereof. The lengths 76 of the at least three cross-panels 74 are disposed parallel to each other. The lengths 76 of the at least three cross-panels 74 are disposed orthogonally to the lengths 66 of the at least two panels 64 discussed above. For example, the lengths 76 of the at least three cross-panels 74 can extend in a forward direction 80 and the rearward direction 82. The at least three cross-panels 74 are spaced apart from each other.

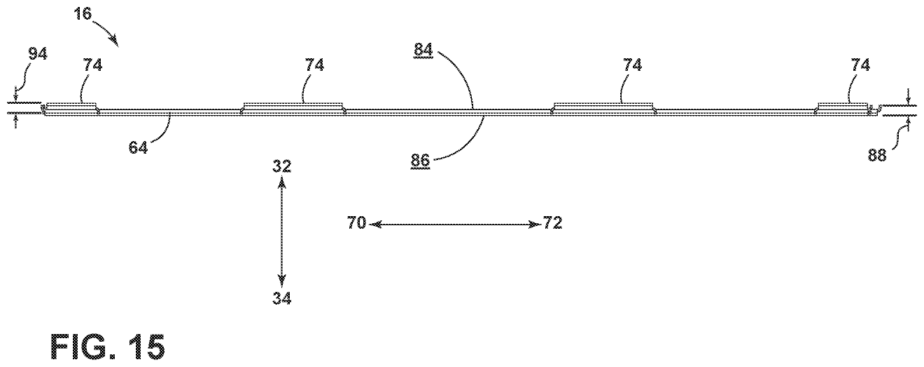

Each of the at least two panels 64 has a top surface 84, a bottom surface 86, and a thickness 88 (see FIG. 15) therebetween. The thickness 88 is orthogonal to the length 66 and the width 68 of the panel 64 (e.g., in the upward direction 32 and the downward direction 34). The thickness 88 is much less than the length 66 and the width 68. For example, each of the at least two panels 64 can be formed of sheet metal or a plastic sheet.

Likewise, each of the at least three cross-panels 74 has a top surface 90, a bottom surface 92, and a thickness 94 therebetween. The thickness 94 is orthogonal to the length 76 and the width 78 of the panel 74 (e.g., in the upward direction 32 and the downward direction 34). The thickness 94 is much less than the length 76 and the width 78. For example, each of the at least three cross-panels 74 can be formed of sheet metal or a plastic sheet.

In embodiments, the platform 16 forms a grid 96 of columns 98 and rows 100 (from the perspective of looking in the downward direction 34 above the platform 16), with the columns 98 spaced apart from each other and the rows 100 spaced apart from each other (e.g., along the horizontal plane). The at least two panels 64 represent the columns 98 and the at least three cross-panels 74 represent the rows 100, or vice-versa. For example, as illustrated, the at least three cross-panels 74 are layered upon the at least two panels 64. In such embodiments, the bottom surfaces 92 of the at least three cross-panels 74 contact the top surfaces 84 of the at least two panels 64. The opposite arrangement is just as possible, with the at least two panels 64 layered upon the at least three cross 74 panels. In such embodiments, the bottom surfaces 86 of the at least two panels 64 contact the top surfaces 90 of the at least three cross-panels 74.

At least a portion of the apertures 62 of the platform 16, those which provide fastening opportunities for the induction coil 14, are disposed through the at least three cross-panels 74 (e.g., through the thickness 94 thereof). In some embodiments, at least a portion of the apertures 62 of the platform 16 are disposed through the at least two panels 64 (e.g., through the thickness 88 thereof). At least some of those apertures 62 through the at least two panels 64 are aligned with at least some of the apertures 62 through the at least three cross-panels 74. For example, the aperture 62a (FIG. 13) is aligned with the aperture 62b (FIG. 14). The alignment provides a fastening opportunity not only for the induction coil 14 to the platform 16 but also for the at least two panels 64 to the at least three cross-panels 74. The apertures 62 through the at least two panels 64 and the apertures 62 through the at least three cross-panels 74 can be positioned to permit adjustment of the relative positioning of the at least two panels 64 and the at least three cross-panels 74 to accommodate the fastening of induction coils 14 of different sizes and to accommodate the repositioning of the induction coils 14.

In embodiments, the apertures 62 of the platform 16 include multiple groupings 102 (see FIG. 13) of at least three apertures 62. For example, in reference to FIG. 13, there are ten groupings 102. “Groupings” here means the at least three apertures 62 (e.g., apertures 62 through the at least three cross-panels 74) fit within a circle 104 (e.g., at the horizontal plane) having a diameter 106 of 30 mm or less, or 25 mm or less. For example, the apertures 62c-62e are part of the grouping 102a, the apertures 62f-62h are part of the grouping 102b, and the apertures 62i-62k are part of the grouping 102c and so on.

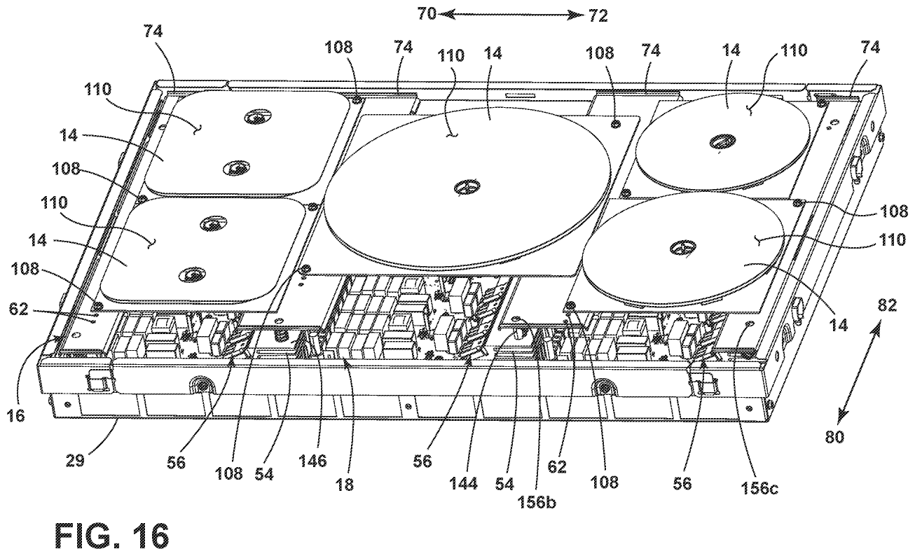

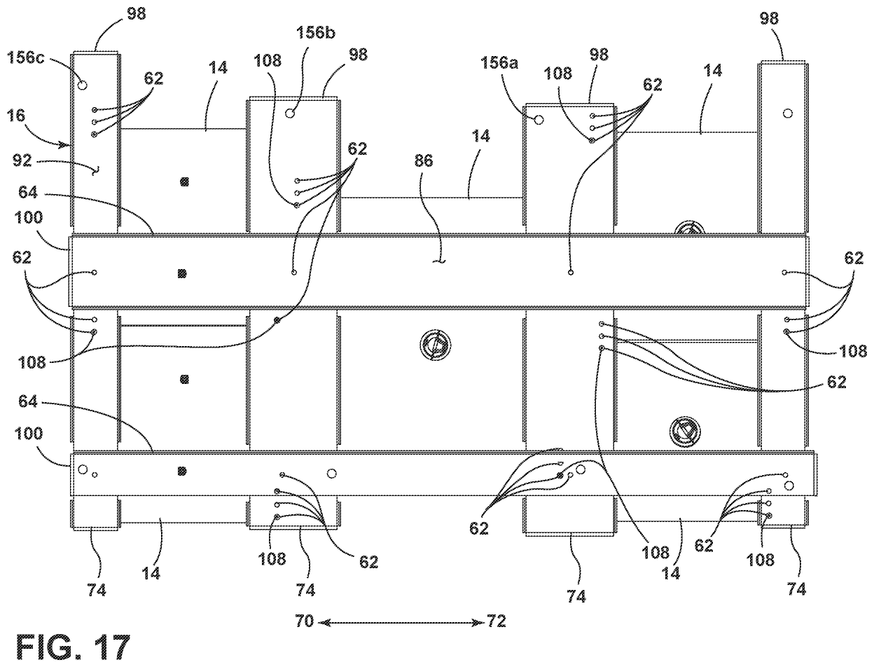

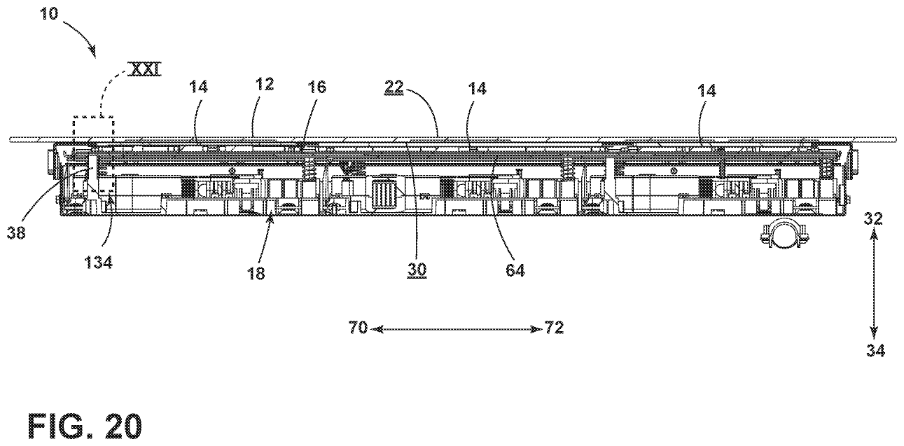

Referring additionally to FIGS. 16-20, the induction coil 14 is disposed on the platform 16. The induction coil 14 is fastened to the platform 16 with fasteners 108 (see, e.g., FIG. 16). The fasteners 108 extend through a portion of the apertures 62 of the platform 16, for example, the apertures 62 through the cross-panels 74 and any apertures 62 of the panels 64 aligned with the apertures 62 of the cross-panels 74. Each induction coil 14 includes a top surface 110 and a bottom surface 112. The bottom surface 112 of the induction coil 14 faces, and can contact, the platform 16. The top surface 110 of the induction coil 14 faces and contacts the bottom surface 30 of the substrate 12.

The apertures 62 of the platform 16 are positioned to permit fastening of the induction coil 14 in one of several positions. For example, with reference to the induction coil 14, the groupings 102a and 102c of the apertures 62c-h permits the induction coil 14 to be fastened further in the forward direction 80 than the position illustrated.

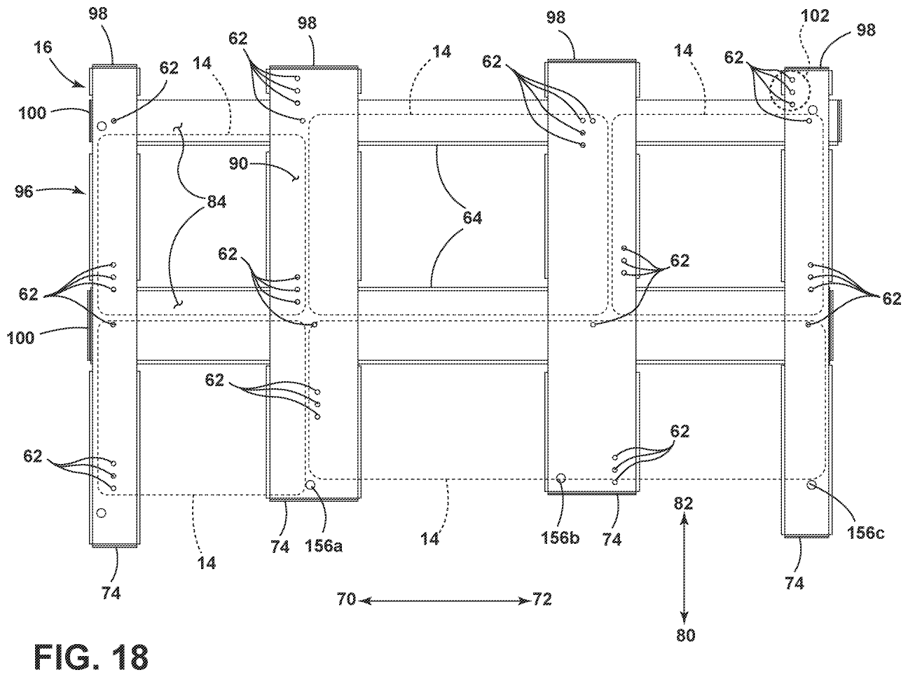

In addition, the apertures 62 of the platform 16 are positioned to permit fastening of several of the induction coils 14 of more than one size in more than one spatial arrangement. The cooktop 10 as illustrated includes more than one induction coil 14. For example, at FIG. 16, the cooktop 10 includes five induction coils 14—two smaller ones to the left, one larger one in the middle, and two smaller ones to the right. To show the versatility, at FIG. 18, the cooktop 10 also includes five induction coils 14—one larger one but of a different shape than the larger one of FIG. 16, two smaller ones to the left, and two more smaller ones in the reward direction of the larger one. The apertures 62 through the platform 16 allow for repositioning of induction coils 14 and selective positioning of inductive coils 14 of different sizes and in different spatial arrangements.

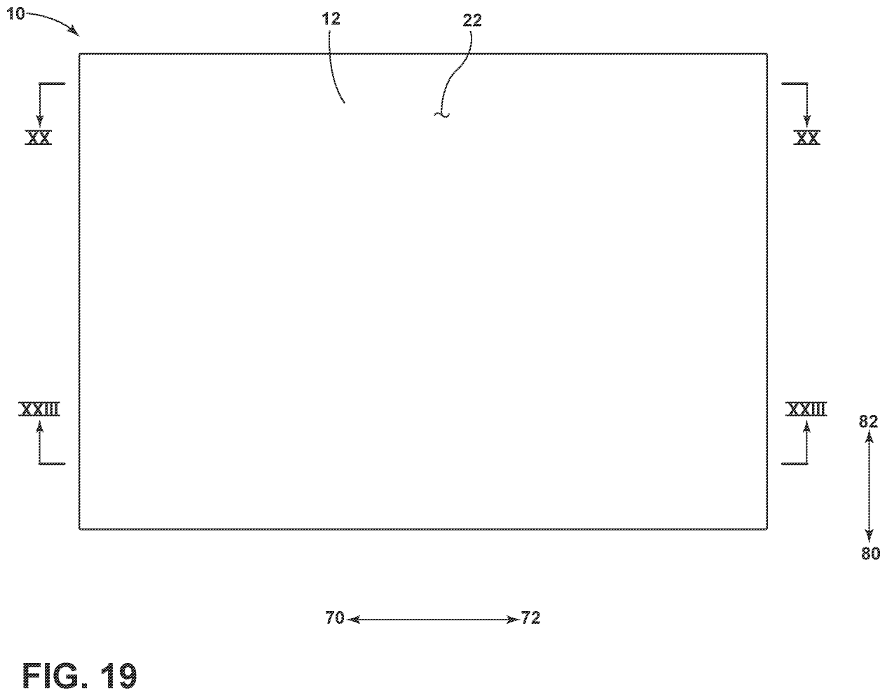

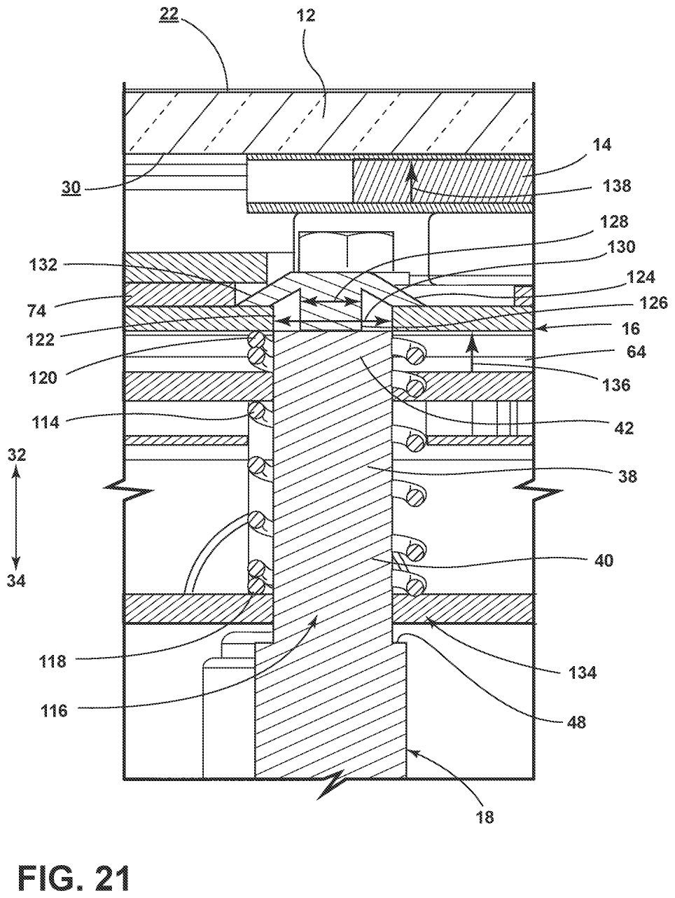

Referring additionally to FIGS. 19-22, in embodiments, the cooktop 10 further includes coiled springs 114. Each of the coiled springs 114 defines an inner core 116 (see FIG. 21). Each of the coiled springs 114 has a bottom end 118 and a top end 120. Each of the coiled springs 114 is disposed around a different one of the studs 38 of the structural support 18, with the stud 38 extending vertically through the inner core 116 of the coiled spring 114. More particularly, the top portion 42 of the stud 38 is disposed within the coiled spring 114 and the bottom portion 40 of the coiled spring 114 is disposed on the ledge 48 of the stud 38.

In such embodiments, the platform 16 includes apertures 122 that are aligned with the studs 38 and through which the studs 38 of the structural support 18 can extend. For example, the cross-panels 74 include the apertures 122 through which the studs 38 extend. The panels 64 include the apertures 122 aligned with the apertures 122 of the cross-panels 74 through which the studs 38 extend. The studs 38 thus help maintain positioning of the platform 16 relative to the structural support 18. The bottom surface 86, 92 of the platform 16, whether provided by the cross-panels 74 or the panels 64, sets upon the top end 120 of each of the coiled springs 114.

In embodiments (see, e.g., FIG. 21), the studs 38 of the structural support 18 each include a head 124 that is configured to permit snap-fit coupling of the head 124 over the platform 16. For example, the head 124 can include a vertical portion 126 extending from the top portion 42 of the stud 38. A horizontal cross-section of the vertical portion 126 has a diameter 128 less than a diameter 130 of the aperture 122 of the platform 16 through which the vertical portion 126 extends. The head 124 can further include downward extending tabs 132 that project from the vertical portion 126. When the head 124 is placed through the aperture 122, the aperture 122 compresses the downward extending tabs 132 until the downward extending tabs 132 clear the aperture 122, and then the downward extending tabs 132 contact the top surface 84, 90 of the platform 16 (e.g., as provided by the at least two panels 64 and the at least three cross-panels 74 respectively). The snap-fit coupling helps prevent the coiled springs 114 from lifting the platform 16 off of the studs 38 of the structural support 18.

The coiled springs 114 are in a partially excited state 134 pushing (e.g., applies a force 136 to) the platform 16 in the upward direction 32. The top surface 110 of the induction coil 14, because of the force 136, contacts the bottom surface 30 of the substrate 12. The force 136 upon the platform 16 causes the induction coil 14 (or induction coils 14, as the case may be) to impart a force 138 in the upward direction 32 upon the bottom surface 30 of the substrate 12. The force 138 on the bottom surface 30 of the substrate 12 is insufficient to cause the substrate 12 to flex, such as convexly in the upward direction 32. Because the substrate 12 does not flex, the coiled springs 114 do not impart a tensile stress within the substrate 12 contiguous with the top surface 22 of the substrate 12. Without such a tensile stress, the substrate 12 is more able to resist impact events from the external environment 20 (e.g., the vessel 24 is dropped) on the top surface 22 of the substrate 12.

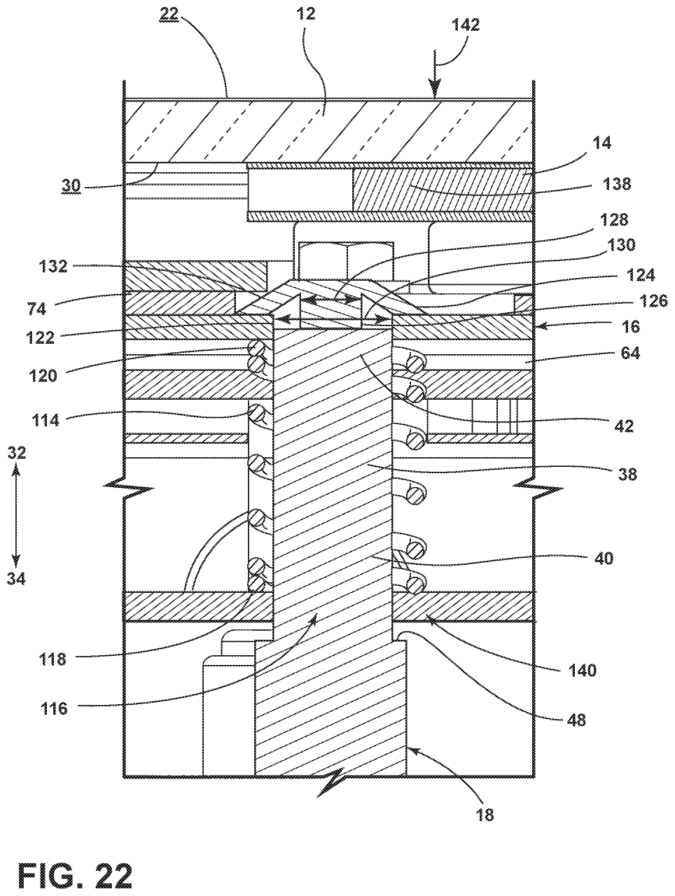

Further, even in the partially excited state 134, the coiled springs 114 have room for further excitement to a more excited state 140 (see FIG. 22) when a force 142 in the downward direction 34 is applied to the top surface 22 of the substrate 12. The coiled springs 114 are thus able to dampen an impact of the vessel 24 upon the top surface 22 of the substrate 12.

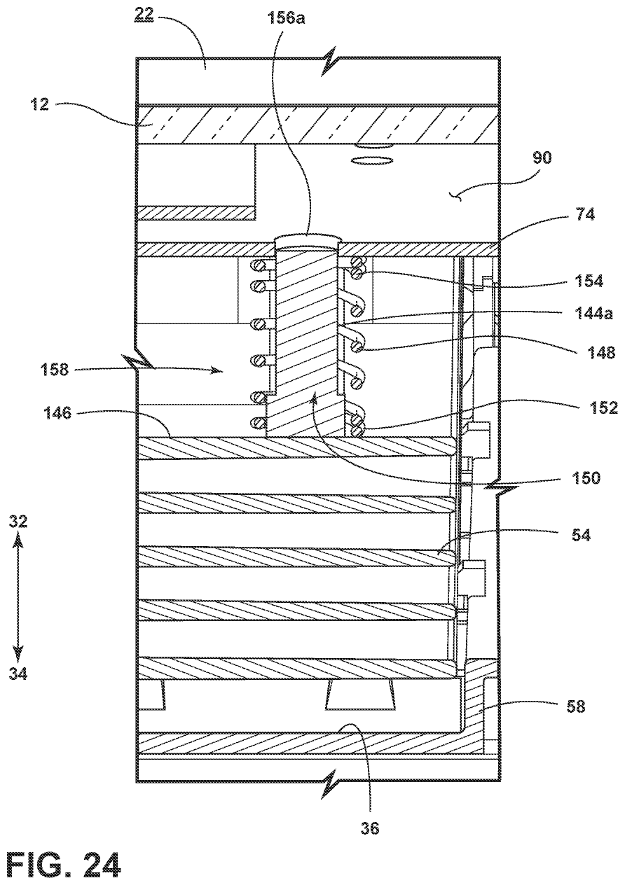

Referring additionally to FIG. 24, the heat sink 54 includes an additional stud 144 (e.g., in addition to the studs 38 of the structural support 18). The additional stud 144 extends in the upward direction 32 from a top 146 of the heat sink 54. Each of the heat sinks 54 can include the additional stud 144. The cooktop 10 in such embodiments includes an additional coiled spring 148 (e.g., in addition to the coiled springs 114 between the structural support 18 and the platform 16). The additional coiled spring 148 defines an inner core 150. The additional coiled spring 148 includes a bottom end 152 and a top end 154. The additional coiled spring 148 is disposed around the additional stud 144 of the heat sink 54. The additional stud 144 extends upward through the inner core 150 of the additional coiled spring 148. The bottom end 152 of the additional coiled spring 148 sits upon the top 146 of the heat sink 54.

In such embodiments where the heat sinks 54 include the additional studs 144, the platform 16 further includes additional apertures 156 (e.g., in addition to the apertures 122 aligned with the studs 38 of the structural support 18) that are aligned with the additional studs 144 of the heat sink 54. For example, the additional aperture 156a is aligned with the additional stud 144a, the additional aperture 156b is aligned with the additional stud 144b, the additional aperture 156c is aligned with the additional stud 144c, and so on. The bottom surface 86, 92 of the platform 16 (e.g., as provided by the at least two panels 64 and the at least three cross-panels 74 respectively) is set upon the top end 154 of the additional coiled spring 148. Like the coiled springs 114, the additional coiled springs 148 are in a partially excited state 158 pushing the platform 16 in the upward direction 32 so that the top surface 110 of the induction coils 14 contact the bottom surface 30 of the substrate 12. The additional coiled springs 148 cause the induction coils 14 to impart the force 138 upon in the upward direction 32 upon the bottom surface 30 of the substrate 12. However, the force 138 on the bottom surface 30 of the substrate 12 is insufficient to cause the substrate 12 to flex. In the partially excited state 134, the additional coiled springs 148 have room for further excited to a more excited state (not separately shown but just like at FIG. 22) when the force 142 in the downward direction 34 is applied to the top surface 22 of the substrate 12. The additional studs 144 can enter and extend through the additional apertures 156 of the platform 16.

The cooktop 10 addresses the problems described in the Background in a variety of ways. The positioning of the at least two panels 64 and the at least three cross-panels 74 of the platform 16 is adjustable by the user or otherwise. In addition, the platform 16 provides multiple apertures 62 (including groupings 102 of apertures 62) to permit the user to place induction coils 14 of whatever sizes in whatever places relative to each other. The user now has flexibility to configure the cooktop 10 as they desire. The platform 16 including the at least two panels 64 and the at least three cross-panels 74 in a grid-like arrangement 96 with open spaces uses less material than a platform 16 made of a single contiguous metal sheet.

Further, although the cooktop 10 described herein places the induction coils 14 to contact the bottom surface 30 of the substrate 12 (thus increasing the eddy-current generating performance), the coiled springs 114 and the additional coiled springs 148 cause the induction coils 14 to impart the force 138 in the upward direction 32 on the substrate 12 that is insufficient to cause the substrate 12 to flex. Thus, no tensile stress upon to the external environment 20 is generated.

According to a first aspect of the present disclosure, a cooktop comprises: (a) a substrate comprising (i) a top surface configured to accept a vessel placed thereupon for heating and (ii) a bottom surface, the top surface and the bottom surface facing in generally opposing directions; (b) a structural support disposed below the substrate; (c) a platform disposed above the structural support, the platform comprising apertures; and (d) an induction coil disposed upon the platform and fastened to the platform with fasteners that extend through at least a portion of the apertures of the platform, the induction coil comprising a top surface that faces the bottom surface of the substrate, wherein, the apertures of the platform are positioned to permit fastening of the induction coil in one of several positions or several of the induction coils of more than one size in more than one spatial arrangement.

According to a second aspect of the present disclosure, the cooktop of the first aspect is presented, wherein the structural support comprises a floor and studs that extend upward relative to the floor.

According to a third aspect of the present disclosure, the cooktop of any one of the first through second aspects further comprises: a fan, a printed circuit board, and a heat sink; wherein, the structural support supports the fan, the printed circuit board, and the heat sink. According to a fourth aspect of the present disclosure, the cooktop of any one of the first through third aspects is presented, wherein the structural support comprises two or more trays, each of which are substantially identical and each of which houses a fan, a printed circuit board, and a heat sink.

According to a fifth aspect of the present disclosure, the cooktop of any one of the first through fourth aspects is presented, wherein the platform further comprises at least two panels, each of the at least two panels comprising a length at least 4 times greater than a width thereof, the lengths of the at least two panels disposed parallel to each other, and the at least two panels are spaced apart from each other.

According to a sixth aspect of the present disclosure, the cooktop of the fifth aspect is presented, wherein the platform further comprises at least three cross-panels, each of the at least three cross-panels comprising a length at least 4 times greater than a width thereof, the lengths of the at least three cross-panels disposed parallel to each other but orthogonal to the lengths of the at least two panels, and the at least three cross-panels are spaced apart from each other.

According to a seventh aspect of the present disclosure, the cooktop of the sixth aspect is presented, wherein the at least three cross-panels of the platform are layered upon the at least two panels of the platform, with bottom surfaces of the at least three cross-panels contacting top surfaces of the at least two panels.

According to an eighth aspect of the present disclosure, the cooktop of any one of the sixth through seventh aspects is presented, wherein at least a portion of the apertures of the platform are disposed through the at least three cross-panels.

According to a ninth aspect of the present disclosure, the cooktop of the eighth aspect is presented, wherein at least a portion of the apertures of the platform are disposed through the at least two panels of the platform, wherein at least some of the apertures through the at least two panels of the platform are aligned with at least some of the apertures through the at least three cross-panels of the platform.

According to a tenth aspect of the present disclosure, the cooktop of any one of the first through ninth aspects is presented, wherein the platform forms a grid of columns and rows, the columns spaced apart from each other and the rows spaced apart from each other.

According to an eleventh aspect of the present disclosure, the cooktop of any one of the first through tenth aspects is presented, wherein the apertures of the platform include multiple groupings of at least three apertures.

According to a twelfth aspect of the present disclosure, the cooktop of the second aspect further comprises: coiled springs, each defining an inner core and comprising a bottom end and a top end, each of the coiled springs disposed around a different one of the studs of the structural support with the stud extending vertically through the inner core of the coiled spring.

According to a thirteenth aspect of the present disclosure, the cooktop of the twelfth aspect is presented, wherein the platform comprises (i) apertures through which the studs of the structural support extend and (ii) a bottom surface set upon the top end of each of the coiled springs.

According to a fourteenth aspect of the present disclosure, the cooktop of any one of the twelfth through thirteenth aspects is presented, wherein the studs of the structural support each include a head configured to permit snap-fit coupling of the head over the platform.

According to a fifteenth aspect of the present disclosure, the cooktop of any one of the twelfth through fourteenth aspects is presented, wherein the coiled springs are in a partially excited state pushing the platform in an upward direction so that the top surface of the induction coil contacts the bottom surface of the substrate.

According to a sixteenth aspect of the present disclosure, the cooktop of the fifteenth aspect is presented, wherein (i) the coiled springs cause the induction coil to impart a force in the upward direction upon the bottom surface of the substrate, and (ii) the force on the bottom surface of the substrate is insufficient to cause the substrate to flex.

According to a seventeenth aspect of the present disclosure, the cooktop of any one of the fifteenth through sixteenth aspects is presented, wherein in the partially excited state, the coiled springs have room for further excitement to a more excited state when a force in a downward direction is applied to the top surface of the substrate.

According to an eighteenth aspect of the present disclosure, the cooktop of any one of the fifteenth through seventeenth aspects further comprises: (a) a fan, a printed circuit board, and a heat sink, the heat sink comprising an additional stud that extend in an upward direction from a top of the heat sink; and (b) an additional coiled spring, the additional coiled spring defining an inner core and comprising a bottom end and a top end, the additional coiled spring disposed around the additional stud of the heat sink, with the additional stud extending upward through the inner core of the additional coiled spring and the bottom end of the additional coiled spring sits upon the top of the heat sink; wherein (i) the structural support supports the fan, the printed circuit board, and the heat sink, (ii) the platform further comprises an additional aperture aligned with the additional stud of the heat sink, and (iii) the bottom surface of the platform is set upon the top end of the additional coiled spring.

According to a nineteenth aspect of the present disclosure, a cooktop comprises: (a) a substrate presenting (i) a top surface configured to accept a vessel placed thereupon for heating and (ii) a bottom surface; (b) a structural support disposed below the substrate, the structural support comprising a floor and studs extending upward from the floor; (c) coiled springs, each defining an inner core and comprising a bottom end and a top end, each of the coiled springs disposed around a different one of the studs of the structural support with the stud extending vertically through the inner core of the coiled spring; (d) a platform disposed above the structural support, the platform comprising (i) apertures through which the studs of the structural support extend, (ii) a bottom surface set upon the top end of each of the coiled springs, (iii) at least two panels, each of the at least two panels comprising a length at least 4 times greater than a width thereof, the lengths of the at least two panels disposed parallel to each other, and the at least two panels are spaced apart from each other, (iv) at least three cross-panels, each of the at least three cross-panels comprising a length at least 4 times greater than a width thereof, the lengths of the at least three cross-panels disposed parallel to each other but orthogonal to the lengths of the at least two panels, and the at least three cross-panels are spaced apart from each other, and (v) the at least three cross-panels of the platform are layered upon the at least two panels of the platform, with bottom surfaces of the at least three cross-panels contacting top surfaces of the at least two panels; and (e) an induction coil disposed upon the platform, the induction coil comprising a top surface that faces the bottom surface of the substrate, wherein, the coiled springs are in a partially excited state pushing the platform in an upward direction so that the top surface of the induction coil contacts the bottom surface of the substrate.

According to a twentieth aspect of the present disclosure, the cooktop of the nineteenth aspect is presented, wherein (i) the coiled springs cause the induction coil to impart a force in the upward direction upon the bottom surface of the substrate, (ii) the force on the bottom surface of the substrate is insufficient to cause the substrate to flex, and (iii) in the partially excited state, the coiled springs have room for further excitement to a more excited state when a force in a downward direction is applied to the top surface of the substrate.

It will be understood by one having ordinary skill in the art that construction of the described disclosure and other components is not limited to any specific material. Other exemplary embodiments of the disclosure disclosed herein may be formed from a wide variety of materials, unless described otherwise herein.

For purposes of this disclosure, the term “coupled” (in all of its forms, couple, coupling, coupled, etc.) generally means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components. Such joining may be permanent in nature or may be removable or releasable in nature unless otherwise stated.

It is also important to note that the construction and arrangement of the elements of the disclosure as shown in the exemplary embodiments is illustrative only. Although only a few embodiments of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements shown as multiple parts may be integrally formed, the operation of the interfaces may be reversed or otherwise varied, the length or width of the structures and/or members or connector or other elements of the system may be varied, the nature or number of adjustment positions provided between the elements may be varied. It should be noted that the elements and/or assemblies of the system may be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

It will be understood that any described processes or steps within described processes may be combined with other disclosed processes or steps to form structures within the scope of the present disclosure. The exemplary structures and processes disclosed herein are for illustrative purposes and are not to be construed as limiting.

What is claimed is:

1. A cooktop comprising:
a substrate comprising (i) a top surface configured to accept a vessel placed thereupon for heating and (ii) a bottom surface, the top surface and the bottom surface facing in generally opposing directions;
a structural support disposed below the substrate;
a platform disposed above the structural support, the platform comprising apertures; and
an induction coil disposed upon the platform and fastened to the platform with fasteners that extend through at least a portion of the apertures of the platform, the induction coil comprising a top surface that faces the bottom surface of the substrate,
wherein, the apertures of the platform are positioned to permit fastening of the induction coil in one of several positions or several of the induction coils of more than one size in more than one spatial arrangement.

2. The cooktop of claim 1, wherein
the structural support comprises a floor and studs that extend upward relative to the floor.

3. The cooktop of claim 1 further comprising:
a fan, a printed circuit board, and a heat sink;
wherein, the structural support supports the fan, the printed circuit board, and the heat sink.

4. The cooktop of claim 1, wherein
the structural support comprises two or more trays, each of which are substantially identical and each of which houses a fan, a printed circuit board, and a heat sink.

5. The cooktop of claim 1, wherein
the platform further comprises at least two panels, each of the at least two panels comprising a length at least 4 times greater than a width thereof, the lengths of the at least two panels disposed parallel to each other, and the at least two panels are spaced apart from each other.

6. The cooktop of claim 5, wherein
the platform further comprises at least three cross-panels, each of the at least three cross-panels comprising a length at least 4 times greater than a width thereof, the lengths of the at least three cross-panels disposed parallel to each other but orthogonal to the lengths of the at least two panels, and the at least three cross-panels are spaced apart from each other.

7. The cooktop of claim 6, wherein
the at least three cross-panels of the platform are layered upon the at least two panels of the platform, with bottom surfaces of the at least three cross-panels contacting top surfaces of the at least two panels.

8. The cooktop of claim 6, wherein
at least a portion of the apertures of the platform are disposed through the at least three cross-panels.

9. The cooktop of claim 8, wherein
at least a portion of the apertures of the platform are disposed through the at least two panels of the platform, wherein at least some of the apertures through the at least two panels of the platform are aligned with at least some of the apertures through the at least three cross-panels of the platform.

10. The cooktop of claim 1, wherein
the platform forms a grid of columns and rows, the columns spaced apart from each other and the rows spaced apart from each other.

11. The cooktop of claim 1, wherein
the apertures of the platform include multiple groupings of at least three apertures.

12. The cooktop of claim 2 further comprising:
coiled springs, each defining an inner core and comprising a bottom end and a top end, each of the coiled springs disposed around a different one of the studs of the structural support with the stud extending vertically through the inner core of the coiled spring.

13. The cooktop of claim 12, wherein
the platform comprises (i) apertures through which the studs of the structural support extend and (ii) a bottom surface set upon the top end of each of the coiled springs.

14. The cooktop of claim 12, wherein
the studs of the structural support each include a head configured to permit snap-fit coupling of the head over the platform.

15. The cooktop of claim 12, wherein
the coiled springs are in a partially excited state pushing the platform in an upward direction so that the top surface of the induction coil contacts the bottom surface of the substrate.

16. The cooktop of claim 15, wherein
the coiled springs cause the induction coil to impart a force in the upward direction upon the bottom surface of the substrate, and
the force on the bottom surface of the substrate is insufficient to cause the substrate to flex.

17. The cooktop of claim 15, wherein
in the partially excited state, the coiled springs have room for further excitement to a more excited state when a force in a downward direction is applied to the top surface of the substrate.

18. The cooktop of claim 15 further comprising:
a fan, a printed circuit board, and a heat sink, the heat sink comprising an additional stud that extend in an upward direction from a top of the heat sink; and
an additional coiled spring, the additional coiled spring defining an inner core and comprising a bottom end and a top end, the additional coiled spring disposed around the additional stud of the heat sink, with the additional stud extending upward through the inner core of the additional coiled spring and the bottom end of the additional coiled spring sits upon the top of the heat sink;
wherein, the structural support supports the fan, the printed circuit board, and the heat sink,
wherein, the platform further comprises an additional aperture aligned with the additional stud of the heat sink, and
wherein, the bottom surface of the platform is set upon the top end of the additional coiled spring.

19. A cooktop comprising:
a substrate presenting (i) a top surface configured to accept a vessel placed thereupon for heating and (ii) a bottom surface;
a structural support disposed below the substrate, the structural support comprising a floor and studs extending upward from the floor;
coiled springs, each defining an inner core and comprising a bottom end and a top end, each of the coiled springs disposed around a different one of the studs of the structural support with the stud extending vertically through the inner core of the coiled spring;
a platform disposed above the structural support, the platform comprising (i) apertures through which the studs of the structural support extend, (ii) a bottom surface set upon the top end of each of the coiled springs, (iii) at least two panels, each of the at least two panels comprising a length at least 4 times greater than a width thereof, the lengths of the at least two panels disposed parallel to each other, and the at least two panels are spaced apart from each other, (iv) at least three cross-panels, each of the at least three cross-panels comprising a length at least 4 times greater than a width thereof, the lengths of the at least three cross-panels disposed parallel to each other but orthogonal to the lengths of the at least two panels, and the at least three cross-panels are spaced apart from each other, and (v) the at least three cross-panels of the platform are layered upon the at least two panels of the platform, with bottom surfaces of the at least three cross-panels contacting top surfaces of the at least two panels; and
an induction coil disposed upon the platform, the induction coil comprising a top surface that faces the bottom surface of the substrate,
wherein, the coiled springs are in a partially excited state pushing the platform in an upward direction so that the top surface of the induction coil contacts the bottom surface of the substrate.

20. The cooktop of claim 19, wherein
the coiled springs cause the induction coil to impart a force in the upward direction upon the bottom surface of the substrate,
the force on the bottom surface of the substrate is insufficient to cause the substrate to flex, and
in the partially excited state, the coiled springs have room for further excitement to a more excited state when a force in a downward direction is applied to the top surface of the substrate.
